(19) United States
(12) Patent Application Publication
(10) Pub. No.: US 2024/0312950 A1
(43) Pub. Date: Sep. 19, 2024

(54) SEMICONDUCTOR DEVICE

(71) Applicant: Renesas Electronics Corporation, Tokyo (JP)

(72) Inventors: Takaya HOSHI, Tokyo (JP); Fumiaki AGA, Tokyo (JP)

(21) Appl. No.: 18/439,249

(22) Filed: Feb. 12, 2024

(30) Foreign Application Priority Data
Mar. 16, 2023 (JP) 2023-042393

(51) Int. Cl. H01L 23/00; H01L 23/498

(52) U.S. Cl. CPC H01L 24/49; H01L 23/49838; H01L 24/48; H01L 2224/48091; H01L 2224/48108; H01L 2224/48227; H01L 2224/49051; H01L 2224/49052; H01L 2224/4917; H01L 2224/49171; H01L 2924/386

(57) ABSTRACT

A plurality of wires of a semiconductor device includes: a first wire connected to each of an end portion electrode and a first terminal of a plurality of terminals; and a second wire connected to each of a non-end portion electrode and a second terminal of the plurality of terminals. A loop height of the first wire is greater than a loop height of the second wire.

### CROSS-REFERENCE TO RELATED APPLICATIONS

The disclosure of Japanese Patent Application No. 2023-042393 filed on Mar. 16, 2023, including the specification, drawings and abstract is incorporated herein by reference in its entirety.

### BACKGROUND

The present disclosure relates to a semiconductor device.

Here, there are disclosed techniques listed below.
[Patent Document 1] Japanese Unexamined Patent Application Publication No. 2006-319237
[Patent Document 2] Japanese Unexamined Patent Application Publication No. 2018-107296

Patent Document 1 discloses a semiconductor device in which a terminal arranged on a wiring substrate and an electrode of a semiconductor chip mounted on the wiring substrate are electrically connected with each other via a wire.

Patent Document 2 discloses a semiconductor device in which a bending angle of a neck portion of one of a plurality of wires respectively connected to electrodes of a semiconductor chip is greater than that of others of the plurality of wires.

### SUMMARY

From the viewpoint of improving the performance of a semiconductor device, for example, it is desirable that a connecting reliability of a connecting portion between an electrode of a semiconductor chip and a wire is high. The inventors of the present application have found that the connecting reliability of a wire, which is located at a specific position, of a plurality of wires connected with the semiconductor chip may be decreased compared to that of other wires of the plurality of wires.

Other objects and novel features will become apparent from the description of this specification and the accompanying drawings.

A semiconductor device according to one embodiment, includes: a wiring substrate having a first surface, and a plurality of terminals arranged on the first surface; a semiconductor chip having a second surface facing the first surface, a third surface opposite the second surface, and a plurality of electrodes arranged on the third surface; a plurality of wires electrically connecting the plurality of electrodes and the plurality of terminals, respectively, with each other; and a sealing body sealing the semiconductor chip, the plurality of wires, and the first surface of the wiring substrate. Here, the semiconductor chip is mounted on the wiring substrate. Also, the plurality of electrodes includes a plurality of first row electrodes arranged along a first side of the third surface. Also, any ones of the plurality of wires are connected with the plurality of first row electrodes. Also, the plurality of first row electrodes includes: a first end portion electrode arranged at a one end portion of an arrangement of the plurality of first row electrodes; a second end portion electrode arranged at an another end portion of the arrangement of the plurality of first row electrodes; and a first non-end portion electrode arranged between the first end portion electrode and the second end portion electrode. Also, the plurality of terminals includes: a first terminal; and a second terminal. Also, the plurality of wires includes: a first wire connected to each of the first end portion electrode and the first terminal; and a second wire connected to each of the first non-end portion electrode and the second terminal. Further, a loop height of the first wire is greater than a loop height of the second wire.

According to the above embodiment, it is possible to improve the performance of the semiconductor device.

### BRIEF DESCRIPTION OF THE DRAWINGS

FIG. 1 is an upper surface view of a semiconductor device according to one embodiment.

FIG. 2 is a lower surface view of the semiconductor device shown in FIG. 1.

FIG. 3 is a cross-sectional view taken along an A-A line shown in FIG. 1.

FIG. 4 is an upper surface view showing a state that a sealing body shown in FIG. 1 is removed.

FIG. 5 is an enlarged plan view at A portion shown in FIG. 4.

FIG. 6 is an enlarged plan view at B portion shown in FIG. 4.

FIG. 7 is an enlarged cross-sectional view taken along a B-B line shown in FIG. 5.

FIG. 8 is an enlarged cross-sectional view taken along a C-C line shown in FIG. 5.

FIG. 9 is an enlarged cross-sectional view taken along a D-D line shown in FIG. 6.

FIG. 10 is an enlarged cross-sectional view showing a state that wires shown in FIGS. 7, 8 and 9 are superimposed with each other.

FIG. 11 is an enlarged cross-sectional view taken along an extending direction of the wire which is connected to a corner portion electrode shown in FIG. 5 or a corner portion electrode shown in FIG. 6.

FIG. 12 is an enlarged plan view showing a portion of a semiconductor device according to a modified example with respect to FIG. 4.

FIG. 13 is an enlarged cross-sectional view showing a state that a wire connected to an end portion electrode shown in FIG. 5, a wire connected to a non-end portion electrode shown in FIG. 5, and a wire connected to a second row electrode shown in FIG. 12 are superimposed with each other.

FIG. 14 is an enlarged plan view showing a portion of a semiconductor device according to a modified example with respect to FIG. 12.

FIG. 15 is an enlarged cross-sectional view showing a state that a wire connected to an end portion electrode shown in FIG. 14, a wire connected to a non-end portion electrode shown in FIG. 14, a wire connected to a corner portion electrode shown in FIG. 14, and a wire connected to a second row electrode shown in FIG. 12 are superimposed with each other.

FIG. 16 is an explanatory view for defining a neck angle of a wire.

FIG. 17 is an enlarged cross-sectional view showing a modified example with respect to FIGS. 7 and 9.

### DETAILED DESCRIPTION

### Description of Forms, Basic Terms and Usage in this Application

In the present application, the description of the embodiment will be divided into a plurality of sections or the like as required for convenience, but unless expressly stated otherwise, these are not independent of each other, and each part of a single example, one of which is a partial detail or a part or all of the other, whether before or after the description, or the like, is modified example or the like. In principle, descriptions of similar parts are omitted. Also, each component in an embodiment is not essential, unless expressly stated otherwise, theoretically limited to that number, and obviously otherwise from the context.

Similarly, in the description of the embodiment and the like, “X consisting of A” or the like with respect to the material, composition, and the like does not exclude elements other than A, except when it is clearly indicated that this is not the case and when it is obvious from the context that this is not the case. For example, regarding a component, it means “X including A as a main component” or the like. For example, the term “silicon member” or the like is not limited to pure silicon, and it is needless to say that it also includes a member containing a SiGe (silicon-germanium) alloy, a multi-element alloy containing silicon as its main component, other additives, or the like. In addition, gold plating, Cu layers, nickel plating, and the like, unless otherwise specified, not only pure, but also gold, Cu, nickel, and the like as the main constituent members, respectively, shall be included.

In addition, reference to a specific numerical value or quantity may be greater than or less than that specific numerical value, unless expressly stated otherwise, theoretically limited to that number, and obviously not so from the context.

In the drawings of the embodiments described below, the same or similar parts are denoted by the same or similar symbols or reference numerals, and the description will not be repeated in principle.

In addition, in the attached drawings, hatching and the like may be omitted even in a cross-section when it becomes complicated or when it is clearly distinguished from a gap. In this connection, even if the hole is closed in plan, the outline of the background may be omitted when it is obvious from the description or the like. In addition hatching or dot patterns may be added to indicate that the region is not a void even if it is not a cross-section or to indicate the boundary of the area.

In the following the electrode of the description, semiconductor chip means a member that functions as an external terminal of the semiconductor chip. A pad that is a plate-shaped member having a small area among the electrodes is referred to as an “electrode pad”. In addition, a member formed so as to locally protrude from the base of the electrode is referred to as a “bump electrode” or a “protrusion electrode”. Also, any of the “electrode pad” and the “bump electrode (or protruding electrode)” may be simply referred to as an “electrode”. Further, a structure in which bump electrodes (or protruding electrodes) are formed on electrode pads is sometimes referred to as “electrodes”.

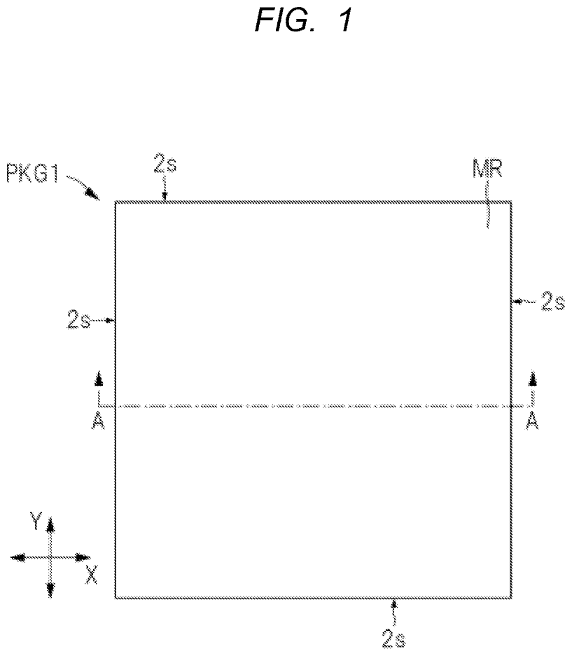

In the following description, the directions of the X direction, the Y direction, and the Z direction may be used. For example, in FIG. 1 to be described later, the X direction and the Y direction are shown. The X direction and the Y direction intersect each other. In the example described below, the X direction is orthogonal to the Y direction. Hereinafter, X-Y plane including the X direction and the Y direction will be described as a plane parallel to the main surface of semiconductor device and the main surface of the mounting substrate.

A plane intersecting X-Y plane (for example, a plane parallel to X-Z plane including the X direction and the Z direction and a plane parallel to Y-Z plane including the Y direction and the Z direction) is referred to as a side surface. In the following explanations, unless explicitly stated otherwise, the term “in plan view” means a view of a plane parallel to X-Y plane. Further, the normal direction with respect to X-Y plane will be described as the “Z direction” or the thickness direction. “Thickness” and “height” refer to the length in the “Z-direction”, unless expressly specified otherwise. The X direction, the Y direction, and the Z direction are directions intersecting each other, and more specifically, directions orthogonal to each other.

### <Semiconductor Device>

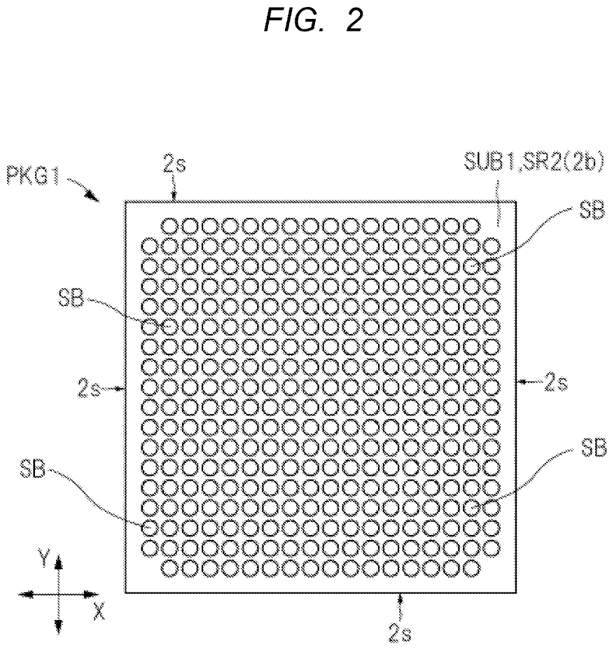

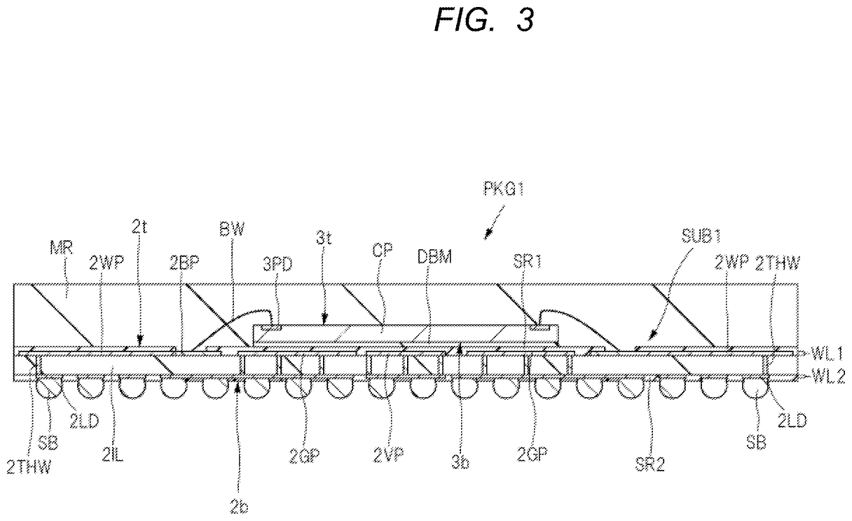

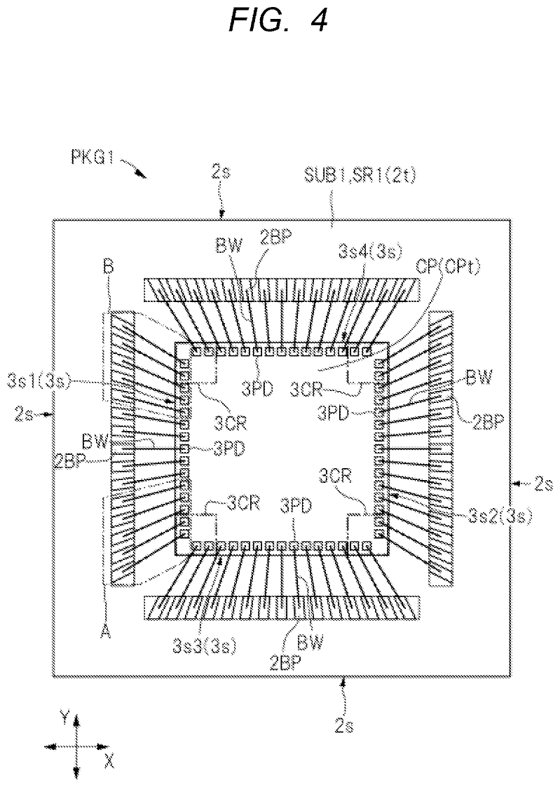

First, an outline of the configuration of a semiconductor device PKG1 of the present embodiment will be described with reference to FIG. 1 to FIG. 4. FIG. 1 is an upper surface view of a semiconductor device according to the present embodiment. FIG. 2 is an upper surface view of a semiconductor device shown in FIG. 1. FIG. 3 is a cross-sectional view taken along an A-A line shown in FIG. 1. FIG. 4 is an upper surface view showing a state that a sealing body shown in FIG. 1 is removed.

The present embodiment of the semiconductor device PKG1 shown in FIG. 3 includes a wiring substrate SUB1, a semiconductor chip CP mounted on the wiring substrate SUB1, a wire BW electrically connected to each of the wiring substrate SUB1 and the semiconductor chip CP, and a sealing body MR sealing the semiconductor chip CP and the wire PKG1.

The wiring substrate SUB1 has an upper surface (surface, main surface, and chip mounting surface) 2t on which the semiconductor chip CP is mounted, and a lower surface (surface, main surface, mounting surface, and second main surface) 2b opposite the upper surface 2t. As shown in FIGS. 2 and 4, the wiring substrate SUB1 has a plurality of sides 2s at an outer edge of each of the upper surface 2t and the lower surface 2b. In the present embodiment, the upper surface 2t (refer to FIG. 3) and the lower surface 2b (see FIG. 2) of the wiring substrate SUB1 are a quadrangular shape. Each of the upper surface 2t and the lower surface 2b has four sides 2s at its outer edge.

The wiring substrate SUB1 includes a wiring layer WL1 in which a terminal (bonding pad, internal interface terminal) 2BP on the upper surface 2t, which is a chip mounting surface, is formed, and a wiring layer WL2 in which a terminal (land, external interface terminal) 2LD on the lower surface 2b, which is a mounting surface, is formed.

Each of the wiring layer WL1 and the wiring layer WL2 has, in addition to the terminal 2BP or the terminal 2LD, a conductive pattern such as a wiring that is a path for supplying an electric signal or power. An insulating layer 2IL is arranged between the wiring layer WL1 and the wiring layer WL2. The wiring layer WL1 and the wiring layer WL2 are electrically connected to each other via a through-hole wiring 2THW which is an interlayer conductive path penetrating through the insulating layer 2IL.

In the embodiment shown in FIG. 3, the wiring layer structure included in the wiring substrate SUB1 is a two layered structure comprised of the wiring layer WL1 and the wiring layer WL2. However, a wiring substrate having three or more wiring layers may be used as modified example for the present embodiment.

The wiring layer WL1 is disposed on the insulating layer 2IL. In the wiring layer WL1, a plurality of terminals 2BP to which a plurality of wires BW is respectively connected is formed. A plurality of terminals 2LD, which is an external terminal, is formed in the wiring layers WL2. The insulating layer 2IL is arranged between the wiring layer WL1 and the wiring layer WL2.

The plurality of terminals 2BP and the plurality of terminals 2LD are electrically connected to each other via a wiring pattern 2WP, a ground pattern 2GP to which a reference potential is supplied, a conductive pattern such as a power supply pattern 2VP to which a power supply potential is supplied, and a through-hole wiring 2THW.

The wiring layer WL1 is covered with an insulating film (solder resist film) SR1. An opening is formed in the insulating film SR1, and each of the plurality of terminals 2BP is exposed from the insulating film SR1 in the opening. The wiring layer WL2 is covered with an insulating film (solder resist film) SR2. An opening is formed in the insulating film SR2, and each of the plurality of terminals 2LD is exposed from the insulating film SR2 in the opening.

In the embodiment shown in FIG. 3, a solder ball (solder material, external terminals, electrodes, external electrodes) SB is connected to each of the plurality of terminals 2LD. The solder ball SB is a conductive member that electrically connects the plurality of terminals 2LD with a plurality of terminals (not shown) on a mounting substrate (not shown) when the semiconductor device PKG1 is mounted on the mounting substrate. The solder ball SB is, for example, a so-called lead-free solder material that is substantially not containing lead (Pb). Examples of lead-free solders include, for example, tin (Sn), tin-bismuth (Sn—Bi), tin-copper-silver (Sn—Cu—Ag), tin-copper (Sn—Cu), and the like. Here, the lead-free solder means that the content of lead (Pb) is less than or equal to 0.1 wt %, and this content is defined as a standard of RoHS (Restriction of Hazardous Substances directive.

As shown in FIG. 2, the plurality of solder ball SB is arranged in a matrix (array-like, matrix-like). Although not shown in FIG. 2, a plurality of terminals 2LD (refer to FIG. 3) to which a plurality of solder balls SB is connected is also arranged in a matrix. In this way, a semiconductor device in which a plurality of external terminals (solder ball SB, terminal 2LD) is arranged in a matrix on the mounting surface of the wiring substrate SUB1 is referred to as an area-array-typed semiconductor device. The area-array-typed semiconductor device is preferable in that an increase in the mounting area of the semiconductor device can be suppressed even if the number of external terminals increases, because the mounting surface (lower surface 2b) of the wiring substrate SUB1 can be effectively used as an arrangement space for external terminals. With higher functionality and higher integration, it is possible to implement a space-saving semiconductor device in which the number of external terminals increases.

As shown in FIG. 3, the semiconductor chip CP includes an upper surface (main surface, front surface) 3t and a lower surface (main surface, back surface) 3b opposite the upper surface 3t. As shown in FIG. 1, the semiconductor chip CP has a quadrangular shape having a planar area smaller than that of the wiring substrate SUB1 in plan view. In the embodiment shown in FIG. 4, the semiconductor chip CP is mounted in a central region (a region including the center of the upper surface 2t) of the wiring substrate SUB1.

As shown in FIG. 4, in plan view, the semiconductor chip CP has a side 3s1 extending in the Y direction, a side 3s2 opposite to the side 3s1, a side 3s3 extending in the X direction intersecting with the Y direction, and a side 3s4 opposite to the side 3s3. In the embodiment shown in FIG. 4, the length of each side 3s is, for example, 5 mm. A plurality of electrodes 3PD is arranged at a peripheral portion of the upper surface 3t of the semiconductor chip CP. In the embodiment shown in FIG. 4, the plurality of electrodes 3PD is arranged in one row along the respective side 3s of the upper surface 3t. However, as will be described later as a modified example, there may be cases where the electrodes 3PD are arranged in plural rows.

As shown in FIG. 3, the semiconductor chip CP is mounted on the wiring substrate SUB1 such that the lower surface 3b faces the upper surface 2t of the wiring substrate SUB1. Specifically, a die bonding material DBM is arranged between the insulating film SR1 having the upper surface 2t of the wiring substrate SUB1 and the lower surface 3b of the semiconductor chip CP. The semiconductor chip CP is bonded and fixed to the insulating film SR1 of the wiring substrate SUB1 via the die bonding material DBM. Such a mounting method is called a face-up mounting method. In the face-up mounting method, a wire BW is used as a conductive member for electrically connecting the electrode 3PD of the semiconductor chip and the terminal 2BP of the wire substrate SUB1.

Further, although not shown, a plurality of semiconductor elements (circuit elements) is formed on a main surface of the semiconductor chip CP a semiconductor element (specifically, forming region provided on an element forming surface of semiconductor substrate which is a base material of the semiconductor chip CP). The plurality of electrodes 3PD is electrically connected to the plurality of semiconductor elements via wirings (not shown) formed in the wiring layers situated inside the semiconductor chip CP (specifically, between upper surface 3t and the semiconductor element forming regions (not shown)).

The semiconductor chip CP (in particular, the substrate of the semiconductor chip CP) is made of, for example, silicon (Si). In addition, an inorganic insulating film covering the base material and the wiring of the semiconductor chip CP is formed on the upper surface 3t, and a part of each of the plurality of electrode 3PD is exposed from the insulating film at an opening formed in the inorganic insulating film. In the present embodiment, the plurality of electrodes 3PD is made of, for example, aluminum (Al).

As shown in FIG. 3, one end portion of the wire BW is bonded to the electrode 3PD. The other end portion of the wire BW is bonded to the terminal 2BP. The wire BW is a metal wire made of a metal material such as gold, copper, or the like. In the present embodiment, the wire BW is made of, for example, copper (Cu). In the embodiment shown in FIG. 3, the end portion connected to the electrode 3PD is the first bond side, and the end portion connected to the terminal 2BP is the second bond side. Such a connection method is called a forward-bonding method. However, although not shown, as a modified example to FIG. 3, the end portion connected to the electrode 3PD side is the second bond side, and the end portion connected to the terminal 2BP is the first bond side. A connecting method such as modified example is called a reverse-bonding method.

A sealing body MR is formed on the upper surface 2t of the wiring substrate SUB1. The sealing member MR is, for example, a resin member obtained by thermally curing a resin material in which an inorganic filler, a black pigment, or the like is mixed with a thermosetting resin serving as a base. Each of the upper surface 2t of the semiconductor chip CP, the plurality of wires BW, the plurality of terminals 2BP, and the wiring substrate SUB1 is sealed by the sealing body MR. By sealing the plurality of wires BW, it is possible to prevent deformation and a short circuit between wires BW adjacent to each other in the semiconductor device PKG1.

### <Details of Wire Periphery>

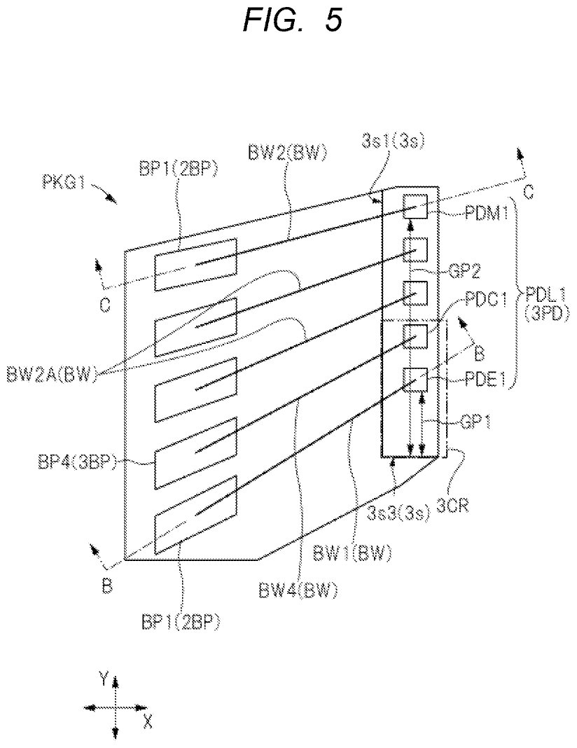

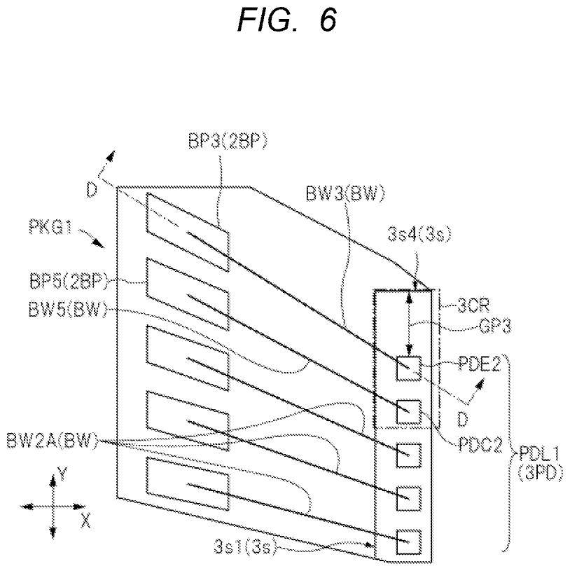

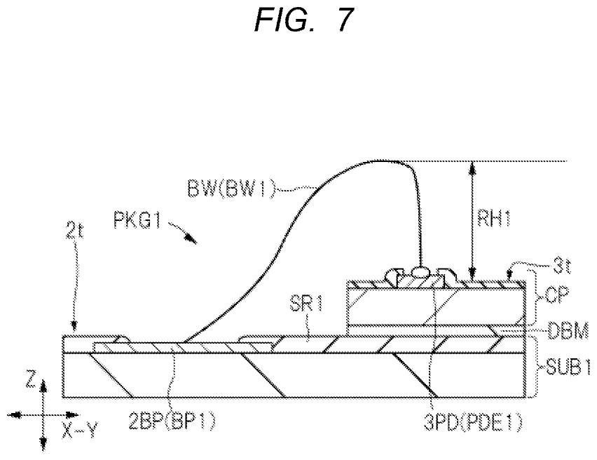

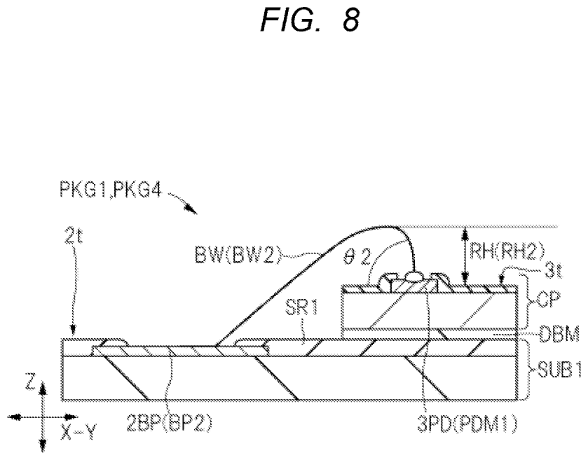

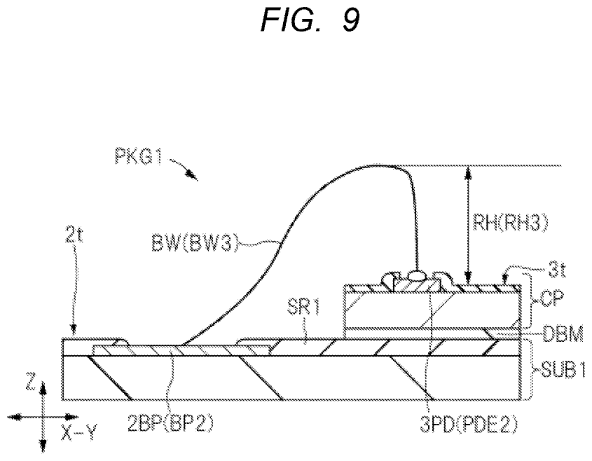

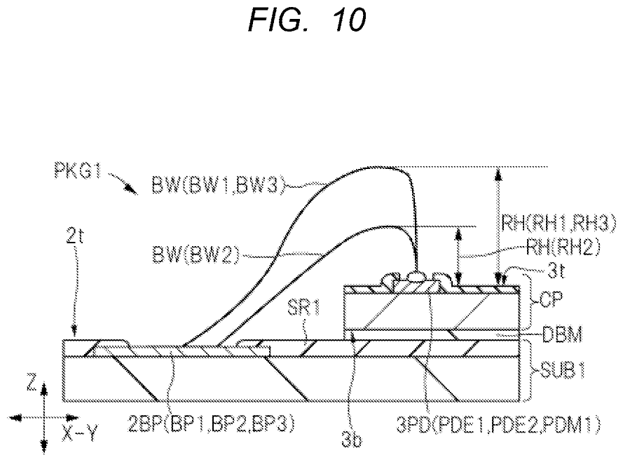

Next, a detailed configuration around the wire BW structure in FIG. 4 will be described. FIG. 5 is an enlarged plan view at A portion shown in FIG. 4. FIG. 6 is an enlarged plan view at B portion shown in FIG. 4. FIG. 7 is an enlarged cross-sectional view taken along a B-B line shown in FIG. 5. FIG. 8 is an enlarged cross-sectional view taken along a C-C line shown in FIG. 5. FIG. 9 is an enlarged cross-sectional view taken along a D-D line shown in FIG. 6. FIG. 10 is an enlarged cross-sectional view showing a state that wires shown in FIGS. 7, 8 and 9 are superimposed with each other. Note that, since the wire BW1 shown in FIG. 7 and the wire BW3 shown in FIG. 9 have the same shapes to each other, in FIG. 10, two wires are illustrated, and one of the two wires is denoted by two reference numerals “BW1, BW3”. Further, in each of FIGS. 7 to 10, the sealing body MR shown in FIG. 3 is not shown.

In the following description, the term “loop height” of the wire may be used. In the present specification, upper surface 3t of the semiconductor-chip CP is used as a reference plane, and the maximal height of the wire BW is referred to as a “loop height”. In the following, relative relationships will be described by comparing “loop height” of a plurality of wires.

As the semiconductor device PKG1 according to the present embodiment, it is preferable to ensure a high-electrical-connection reliability at each junction of a plurality of wires BW for a semiconductor device having a plurality of wire BW.

However, the inventors of the present application have found that, among the plurality of wire BW connected to the semiconductor chip CP, the wire BW disposed at a particular position may have lower reliability of connecting the wire BW and the electrode 3PD as compared with other wire BW. Specifically, a temperature cycling load is applied to the semiconductor package, so that stress is generated in the semiconductor package. It has been found that, among the junctions between the plurality of wire BW and the plurality of electrode 3PD, there is a possibility that the joints may be damaged, particularly at the places where stresses are concentrated and applied.

As shown in FIG. 4, in case of a semiconductor device PKG1 having a semiconductor chip CP having a quadrangular shape in a plan view, a stress concentration tends to occur at the vicinity of each of four corners at which each of the four side 3s of the semiconductor chip intersects with each other. Further, it has been found that the fracture of the bonding portion caused by the stress concentration tends to occur at the bonding boundary between the electrode 3PD and the ball portion of the wire BW when the wire BW made of copper (Cu) is bonded to the electrode made of aluminum (Al).

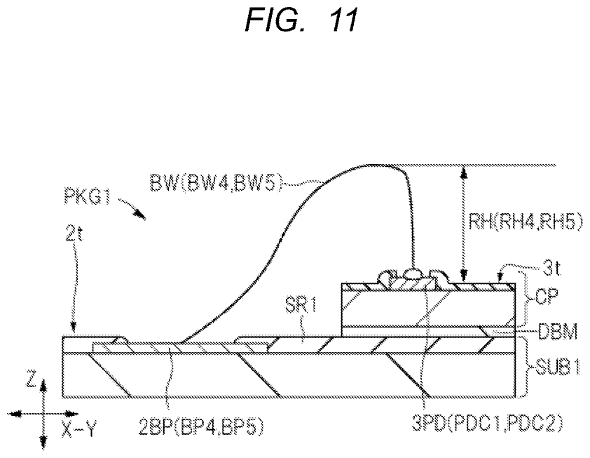

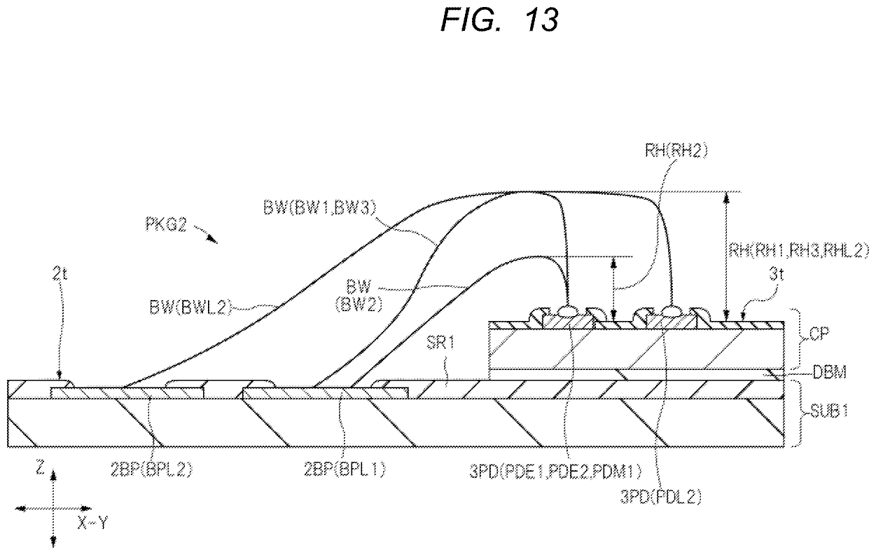

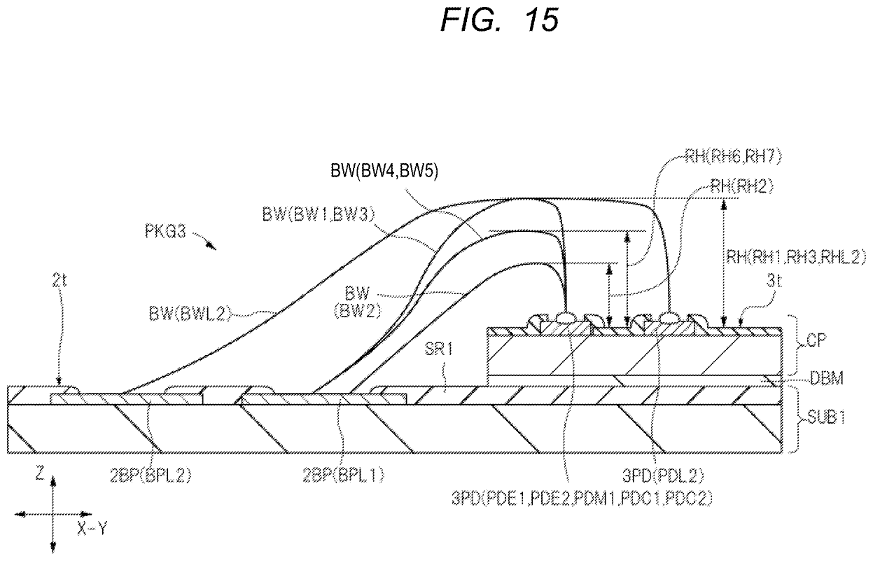

The inventors of the present application have studied methods for vegetating damage to a joint portion between a wire BW and an electrode 3PD due to stress, and have found that damage to the joint portion can be suppressed by increasing the loop-height RH of the wire BW (see FIG. 7 to be described later). The loop height RH is a generic term for the loop height of each of the plurality of wire BW, and includes a loop height RH1 (see FIG. 7), a loop height RH2 (see FIG. 8), a loop height RH3 (see FIG. 9), a loop height RH4 (see FIG. 11), a loop height RH5 (see FIG. 11), a loop height RHL2 (see FIG. 13), a loop height RH6 (see FIG. 15), and a loop height RH (see FIG. 15).

On the other hand, the length of the wire BW is increased when the loop-height RH of the wire BW is increased. The impedance of the current path through the wire BW increases in proportion to the length of the wire BW. Therefore, from the viewpoint of reducing the impedance in the current path, the length of the wire BW is preferably shorter.

Therefore, in the present embodiment, the loop height of the wire 3PD connected to the electrode BW arranged at a place where stress concentration is likely to occur is selectively increased, and the loop height of the wire BW connected to the electrode OOD arranged at a place where stress concentration is unlikely to occur is decreased.

That is, as shown in FIGS. 5 and 6, the plurality of electrodes 3PD includes a plurality of first-row electrodes PDL1 arranged along the side 3s1 of the semiconductor chip CP. The plurality of first row electrodes PDL1 includes an end portion electrode PDE1 (refer to FIG. 5) arranged at one end portion of the arrangement, an end portion electrode PDE2 (see FIG. 6) arranged at the other end portion of the arrangement, and a non-end portion electrode PDM1 arranged between the end portion electrode PDE1 and the end portion electrode PDE2. The plurality of wires BW includes a wire BW1 connected to each of the terminal BP1 of the plurality of terminals 2BP and the end portion electrode PDE1. The plurality of wires BW includes a wire BW2 connected to each of the terminal BP2 of the plurality of terminals 2BP and the non-end portion electrode PDM1.

As shown in FIG. 10, the loop height RH1 of the wire BW1 is greater than the loop height RH2 of the wire BW2. The wire BW1 has a loop height RH1 of, for example, 200 μm. On the other hand, the wire BW2 has a loop height RH2 of, for example, 100 μm.

According to studies by the inventors of the present application, it has been found that the above-described stress concentration is likely to occur at the corners of the semiconductor-chip CP. In addition, stress concentration is less likely to occur at a position where the distance from the corner of the semiconductor chip CP is long. According to studies by the inventors of the present application, when 20% of a length of one side of the semiconductor chip CP is a first length, in the electrode 3PD located in a region where the distance from the corner of the semiconductor chip CP is smaller than the first length, it is preferable to adopt a configuration in which the effect of the stress concentration is taken into account the electrode.

For example, in the present embodiment, the length of each of the four sides 3s included in the semiconductor chip CP is 5 mm. In the semiconductor chip CP, it has been found that the above-described stress-concentration is likely to occur in the electrode 3PD disposed in the square of 1 mm from the corner of the semiconductor chip CP. In each of FIGS. 4 to 6, the area of 1 mm square including one of four corners of upper surface 3t of the semiconductor-chip CP is shown as the corner region 3CR.

In addition, 3PD disposed at a position close to the corner of the semiconductor-chip CP is more likely to be stressed. In the embodiment shown in FIG. 5, the stress concentration is most likely to occur in the end portion electrode PDE1. The distance GP1 from the end portion electrode PDE1 to the side 3s3 intersecting the side 3s1 is less than 1 mm (in other words, less than the first length described above). On the other hand, the distance GP2 from the end portion electrode PDM1 to each side 3s3, 3s4 intersecting the side 3s1 is larger than 1 mm (in other words, the above-described first length).

When a thermal cycling load is applied to the semiconductor device PKG1, a stress concentration occurs at the end portion electrode PDE1. For the present embodiment, since the loop height RH1 of the wire BW1 connected to the end portion electrode PDE1 shown in FIG. 7 is higher than the loop height RH2 of the wire BW2 connected to the non-end portion electrode PDM1 shown in FIG. 8, even if stress concentration occurs, it is possible to suppress the damage against the bonding portion between the wire BW1 and the end portion electrode PDE1.

The loop height RH2 of the wire BW2 connected to the non-end portion electrode PDM1 shown in FIG. 8 is lower than the loop height RH1 of the wire BW1 connected to the end portion electrode PDE1 shown in FIG. 7. In other words, the loop height RH2 of the wire BW2 connected to a portion where stress concentration is unlikely to occur is lower. Therefore, the impedance of the current path including the wire BW2 can be reduced.

As described above, the end portion electrode PDE1 is more susceptible to stress concentration than the non-end portion electrode PDM1. Similarly, stress-concentration is likely to occur in the end portion electrode PDE2 (see FIG. 6) disposed at the end portion of the plurality of first row electrode PDL1 that is opposed to the end portion electrode PDE1. Therefore, in the wire BW3 connected to the end portion electrode PDE2 shown in FIG. 6, it is preferable to take the same countermeasures as the wire BW1 shown in FIG. 5.

That is, as shown in FIG. 6, the plurality of wires BW further includes a wire BW3 connected to each of the end portion electrode PDE2 and the terminal BP3 of the plurality of terminals 2BP. The loop height RH3 of the wire BW3 shown in FIG. 9 is higher than the loop height RH2 of the wire BW2 shown in FIG. 8. The loop height RH3 of the wire BW3 is equal to the loop height RH1 of the wire BW1 shown in FIG. 7, for example, 200 μm. Further, each of the distance GP3 from the end portion electrode PDE2 to the side 3s4, which is intersecting with the side 3s1, shown in FIG. 6 and the distance GP1 from the end portion electrode PDE1 to the side 3s3, which is intersecting with the side 3s1, shown in FIG. 5 is less than 1 mm (in other words, the first length described above).

In the embodiment illustrated in FIG. 4, the wire BW is bonded to all of the electrode 3PD. However, as modified example, a wire BW may not be connected to a part of the plurality of electrode 3PD. As described above, the problem caused by the stress concentration occurs at the bonding interface between the electrode 3PD and the wire BW. Therefore, the electrode 3PD to which the wire BW is not connected is not included in the plurality of first row electrodes PDL1. In other words, one of the plurality of wires BW is connected to the plurality of first row electrodes PDL1.

As described above, the reduction of the bonding reliability affected by the stress concentration tends to occur at the bonding boundary between the wire BW1, which is connected to the end portion electrode PDE1 closest to the corner of the semiconductor chip CP, of the plurality of wires BW and the end portion electrode PDE1. However, in the plurality of wires BW arranged at each corner of the semiconductor chip CP, it is preferable to take the same countermeasures as the wire BW1.

For the present embodiment, similarly to the loop height of the wire BW1, the loop height of each of the plurality of wires BW connected to the electrode 3PD arranged in the corner region 3CR shown in FIGS. 4 to 6 is higher than the loop height RH2 of the wire BW2 shown in FIGS. 5, 8, and 10.

FIG. 11 is an enlarged cross-sectional view taken along an extending direction of the wire which is connected to a corner portion electrode shown in FIG. 5 or a corner portion electrode shown in FIG. 6. For example, as shown in FIG. 5, the plurality of first row electrodes PDL1 further includes a corner portion electrode PDC1 arranged next to the end portion electrode PDE1. The plurality of wires BW further includes a wire BW4 connected to each of the corner portion electrode PDC1 and the terminal BP4 of the plurality of terminals 2BP. The loop height RH4 of the wire BW4 shown in FIG. 11 is higher than the loop height RH2 of the wire BW2 shown in FIG. 8. In the present embodiment case, the loop height RH4 of the wire BW4 is equal to the loop height RH1 of the wire BW1 shown in FIG. 7.

Further, for example, as shown in FIG. 6, the plurality of first row electrodes PDL1 further includes a corner portion electrode PDC2 arranged next to the end portion electrode PDE2. The plurality of wires BW further includes a wire BW5 connected to each of the corner portion electrode PDC2 and the terminal BP5 of the plurality of terminals 2BP. The loop height RH5 of the wire BW5 shown in FIG. 11 is greater than the loop height RH2 of the wire BW2 shown in FIG. 8. In the present embodiment case, the loop height RH5 of the wire BW5 is equal to the loop height RH1 of the wire BW1 shown in FIG. 7.

It should be noted that “the loop height is equal” means that the loop height is the same in design level. Therefore, even when the loop height is slightly different due to mechanical accuracy or the like, if the designed loop height is the same, they are included in the above-described “loop height is equal”. For example, in the embodiment shown in FIG. 10, the design value of the loop height RH2 is 100 μm, while the design value of the loop height RH1 and the loop height RH3 is 200 μm. In this case, an error of about several micrometers may occur between the loop height RH1 and the loop height RH3 due to mechanical accuracy or the like, but in this case, too, it can be said that “the loop height RH1 and the loop height RH3 are equal to each other”. The difference between the loop height RH1 and the loop height RH3 is negligibly smaller than the difference between the loop height RH1 and the loop height RH2.

In the following description, the expression “loop height” is “equal” may be used. In this case, as in the above, it is used in the meaning that “the design value is equal”, so that it also includes cases where the loop height is slightly different, unless explicitly stated to be interpreted in a particularly different sense.

Further, among the plurality of first row electrodes PDL1 shown in FIGS. 5 and 6, the electrode 3PD disposed in the corner region 3CR is only four of the end portion electrode PDE1 (see FIG. 5), the end portion electrode PDE2 (see FIG. 6), the corner portion electrode PDC1 (see FIG. 5), and the corner portion electrode PDC2 (see FIG. 6). Therefore, in the present embodiment, the loop height of each of the plurality of wires BW connected to the plurality of electrodes 3PD arranged between the corner portion electrode PDC1 and the corner portion electrode PDC2 is equal to the loop height RH2 of the wire BW2 shown in FIG. 8, for example, 100 μm.

In FIGS. 5 and 6, a wire BW having a loop height equal to the loop height RH2 of the wire BW2 shown in FIG. 8 is indicated by a reference numeral of a wire BW2A.

<Modified Example when Electrodes are Arranged in Plural Lines>

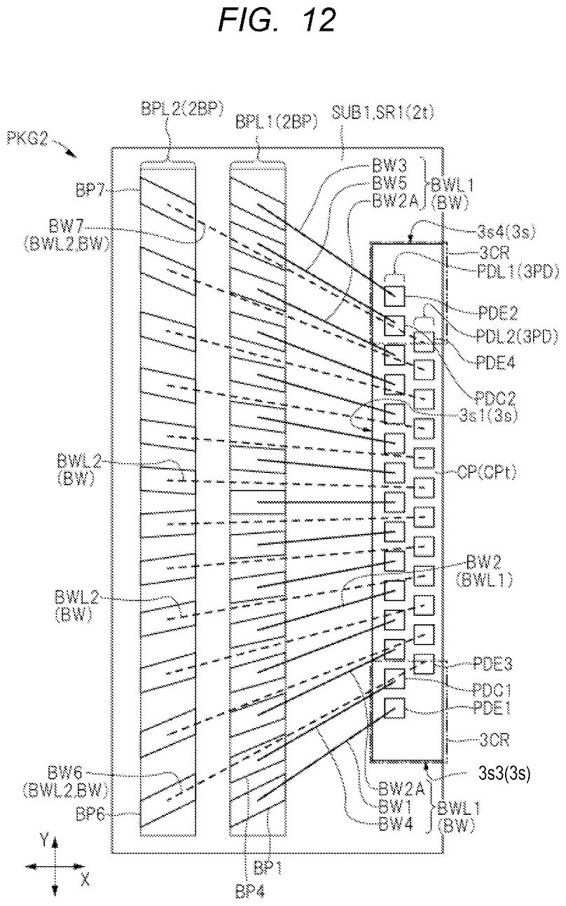

Next, a modified example in which electrodes are arranged in plural rows along one side of the semiconductor chip CP will be described. FIG. 12 is an enlarged plan view showing a portion of a semiconductor device according to a modified example with respect to FIG. 4. In FIG. 12, in order to facilitate identification between the first row wire BWL1 and the second row wire BWL2, each of the plurality of second row wires BWL2 is illustrated by a dotted line. FIG. 13 is an enlarged cross-sectional view showing a state that a wire connected to an end portion electrode shown in FIG. 5, a wire connected to a non-end portion electrode shown in FIG. 5, and a wire connected to a second row electrode shown in FIG. 12 are superimposed with each other.

A semiconductor device PKG2 shown in FIGS. 12 and 13 differs from the semiconductor device PKG1 shown in FIGS. 4 to 11 in that the electrodes 3PD and the terminals 2BP are arranged in a plurality of rows (two rows in FIG. 12).

The plurality of electrodes 3PD included in the semiconductor device PKG2 includes a plurality of second-row electrodes PDL2 arranged at positions farther from the side 3s1 than the plurality of first-row electrodes PDL1 and arranged along the side 3s1 of the semiconductor chip CP. The plurality of wires BW included in the semiconductor device PKG2 includes a plurality of first row wires BWL1 bonded to either one of the plurality of first row electrodes PDL1 and one of the plurality of terminal 2BP. Further, the plurality of wire BW includes a plurality of second row wire BWL2 that are bonded to any one of the plurality of second row electrodes PDL2 and any one of the plurality of terminal 2BP. As shown in FIG. 13, the loop height RHL2 of each of the plurality of second row wire BWL2 is higher than the loop height RH2 of the wire BW2. The second row wire BWL2 has a loop height RHL2 of, for example, 200 μm.

The loop height RHL2 of each of the plurality of second row wires BWL2 is greater than the loop height RH2 of the wire BW2 so that the plurality of second row wires BWL2 is not in contact with the plurality of first row wires BWL1.

A part of the plurality of second row electrode PDL2 (in the example shown in FIG. 12, two second row electrodes PDL2 located at both ends of the arrangement) is disposed in a region to be considered for damages of the joint portion due to the above-described stress concentration, that is, in the corner region 3CR.

Specifically, the plurality of second row electrodes PDL2 of the semiconductor device PKG2 includes an end portion electrode PDE3 arranged at one end portion of the arrangement and an end portion electrode PDE4 arranged at the other end portion of the arrangement. The plurality of wires BW includes a wire BW6 connected to each of the end portion electrode PDE3 and one of the plurality of terminals 2BP (terminal BP6 shown in FIG. 12). The plurality of wires BW includes a wire BW7 connected to each of the end portion electrode PDE4 and one of the plurality of terminals 2BP (terminal BP7 shown in FIG. 12). The distance from the end portion electrode PDE3 to the side 3s3 intersecting the side 3s1 is less than 1 mm (in other words, less than 20% of the length of the side 3s1). Similarly, the distance from the end portion electrode PDE4 to the side 3s4 intersecting the side 3s1 is less than 1 mm (in other words, less than 20% of the length of the side 3s1).

However, as described above, the loop height RHL2 of each of the plurality of second row wire BWL2 is set greater than the loop height RH2 of the wire BW2. Therefore, from the viewpoint of suppressing damages to the portion due to stress concentration, the loop height of the wire BW6 and the wire BW7 disposed at the end portion of the array among the plurality of second row wire BWL2 need not be higher than the loop height of the wire BW disposed at the non-end portion. For example, in the embodiment illustrated in FIG. 12, the loop height RHL2 of the plurality of second row wires BWL2 are equal to each other, for example, 200 μm.

On the other hand, in the present modified example, the respective loop height of each of the plurality of first row wires BWL1 respectively connected to the plurality of first row electrodes PDL1 is the same as that in the semiconductor device PKG1 described with reference to FIGS. 4 to 11.

That is, as shown in FIG. 13, the loop height RH1 of the wire BW1 is higher than the loop height RH2 of the wire BW2. The wire BW1 has a loop height RH1 of, for example, 200 μm. On the other hand, the wire BW2 has a loop height RH2 of, for example, 100 μm. In this case, the loop height RHL2 of each of the plurality of second row wire BWL2 is equal to the loop height of the wire BW1.

Further, the loop height RH3 of the wire BW3 shown in FIG. 13 is higher than the loop height RH2 of the wire BW2. The loop height RH3 of the wire BW3 is equal to the loop height RHL2 of each of the plurality of second row wire BWL2, for example, 200 μm.

The plurality of first row electrodes PDL1 has a corner portion electrode PDC1 arranged next to the end portion electrodes PDE1. The plurality of wires BW further includes a wire BW4 connected to each of the corner portion electrode PDC1 and the terminal BP4 of the plurality of terminals 2BP. The plurality of first row electrodes PDL1 further includes a corner portion electrode PDC2 arranged next to the end portion electrode PDE2. The plurality of wires BW further includes a wire BW5 connected to each of the corner portion electrode PDC2 and the terminal BP5 of the plurality of terminals 2BP.

In the present modified example, the loop height RH4 of the wire BW4 (refer to FIG. 11) and the loop height RH5 of the wire BW5 (see FIG. 11) are designed in view of interfering with the plurality of second-row wire BWL2. For example, in the embodiment shown in FIG. 12, each of the wire BW4 and the wire BW5 does not intersect with the second row wire BWL2 and does not interfere with each other. Therefore, each of the loop height RH4 of the wire BW4 and the loop height RH5 of the wire BW5 is equal to the loop height RH1 of the wire BW1 shown in FIG. 13.

On the other hand, when there is a fear that the wire BW4 and the wire BW5 interfere with the second row wire BWL2, as will be described later as modified example, the loop height BW4 of the wire RH4 (refer to FIG. 11) and the loop height RH5 of the wire BW5 (see FIG. 11) may be designed to be lower than the loop height RHL2 of the second row wire BWL2 which may interfere.

In the embodiment illustrated in FIG. 12, the plurality of terminals 2BP includes a plurality of first row terminals BPL1 arranged along the first direction, and a plurality of second row terminals BPL2 arranged along the first direction at positions farther from the semiconductor chip CP than the plurality of first row terminals BPL1. The plurality of first-row wires BWL1 are connected to the plurality of first-row terminals BPL1. The plurality of second row wires BWL2 are connected to the plurality of second row terminals BPL2. As described above, since the plurality of first row electrodes PDL1 and the plurality of first row terminals BPL1 are connected to each other and the plurality of second row electrodes PDL2 and the plurality of second row terminals BPL2 are connected to each other, it is easy to avoid interference between the plurality of first row wires BWL1 and the plurality of second row wires BWL2.

However, although not shown, the plurality of electrodes 3PD and the plurality of terminal 2BP are connected to each other in various modified example in addition to the embodiment shown in FIG. 12. For example, a part of the plurality of first row electrodes PDL1 may be connected to any one of the plurality of second row terminals BPL2, or a part of the plurality of first row electrodes PDL1 may be connected to any one of the plurality of second row terminals BPL2. Further, for example, one or both of the plurality of electrodes 3PD and the plurality of terminals 2BP may be arranged in three or more rows.

The semiconductor device PKG2 illustrated in FIGS. 12 and 13 are the same as the semiconductor device PKG1 described with reference to FIGS. 1 to 11 except for the above-described differences. Therefore, redundant description will be omitted.

### <Modified Example of Loop Height of First Line Wire>

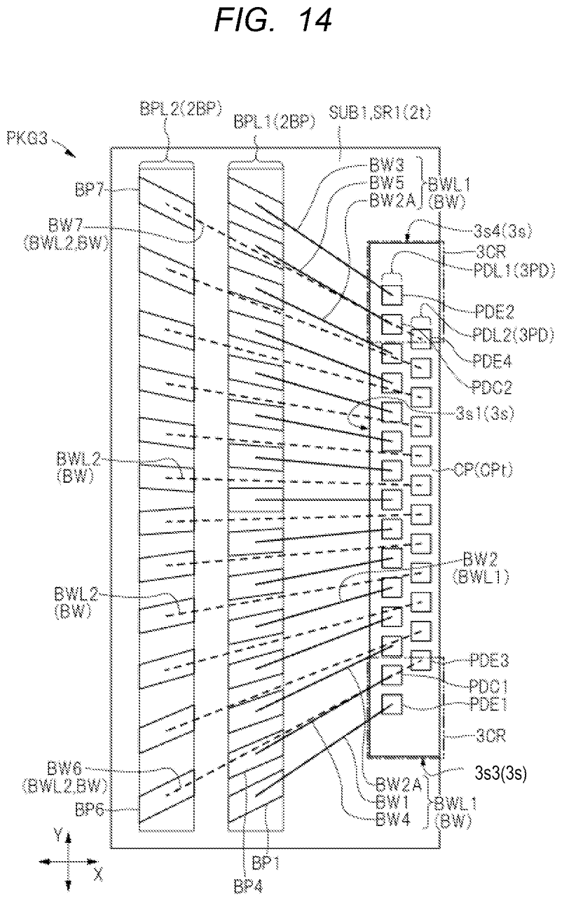

Next, as a modified example with respect to the semiconductor device PKG2 explained by using FIGS. 12 and 13, a modified example of a loop height of the wires BW6, BW7 shown in FIG. 12 will be described. FIG. 14 is an enlarged plan view showing a portion of a semiconductor device according to a modified example with respect to FIG. 12. In FIG. 14, likewise FIG. 12, each of the plurality of second row wire BWL2 is illustrated by a dotted line. FIG. 15 is an enlarged cross-sectional view showing a state that a wire connected to an end portion electrode shown in FIG. 14, a wire connected to a non-end portion electrode shown in FIG. 14, a wire connected to a corner portion electrode shown in FIG. 14, and a wire connected to a second row electrode shown in FIG. 12 are superimposed with each other.

A semiconductor device PKG3 shown in FIGS. 14 and 15 differs from the semiconductor device PKG2 shown in FIGS. 12 and 13 in that the loop height RH6 (see FIG. 15) of the wire BW6 connected to the corner portion electrode PDC1 and the loop height RH7 (refer to FIG. 15) of the wire BW7 connected to the corner portion electrode PDC2 are smaller than the loop height RH1, RH3 (refer to FIG. 15).

As shown in FIG. 15, the semiconductor device PKG3 has a wire BW6 having a loop height RH6 of, for example, 150 μm. That is, the loop height RH6 of the wire BW6 is lower than the loop height RHL2 of each of the plurality of second row wire BWL2 and higher than the loop height RH2 of the wire BW2. Similarly, the semiconductor device PKG3 has a wire BW7 having a loop height RH7 of, for example, 150 μm. That is, the loop height RH7 of the wire BW7 is lower than the loop height RHL2 of each of the plurality of second row wire BWL2 and higher than the loop height RH2 of the wire BW2.

According to the present modified example, the loop height RH6 of the wire BW6 is lower than the loop height RHL2 of each of the plurality of second row wire BWL2 and higher than the loop height of the wire BW2. That is, it is possible to suppress the damage at the joint portion between the corner portion electrode PDC1 and the wire BW6 due to the stress concentration, and to avoid contacting between the wire BW6 and the second row wire BWL2.

Similarly, according to the present modified example, it is possible to suppress a damage at the joint portion between the corner portion electrode PDC2 and the wire BW7 due to stress concentration, and to avoid contacting between the wire BW7 and the second row wire BWL2.

The risk of contacting the first row wire BWL1 and the second row wire BWL2 increases, for example, when the first line wire BWL1 and the second row wire BWL2 intersect with each other in plan view, or when the distance between the first row wire BWL1 and the second row wire BWL2 is small. In the embodiment shown in FIG. 15, the wire BW4, BW5 intersects any of the plurality of second row wire BWL2.

When the first row wire BWL1 and the second row wire BWL2 intersect with each other at a portion overlapping the semiconductor chip CP in plan view, or in the vicinity thereof, the first row wire BWL1 and the second row wire BWL2 are particularly likely to come into contact with each other.

According to the present modified example, since the risk of contacting the first row wire BWL1 and the second row wire BWL2 with each other can be decreased, the plurality of electrodes 3PD and the plurality of terminals 2BP can be laid out more freely.

The semiconductor device PKG3 shown in FIGS. 14 and 15 is the same as the semiconductor device PKG2 described with reference to FIGS. 12 and 13 except for the above-described differences. Therefore, redundant description will be omitted.

### <Modified Example of Wire Loop Shape>

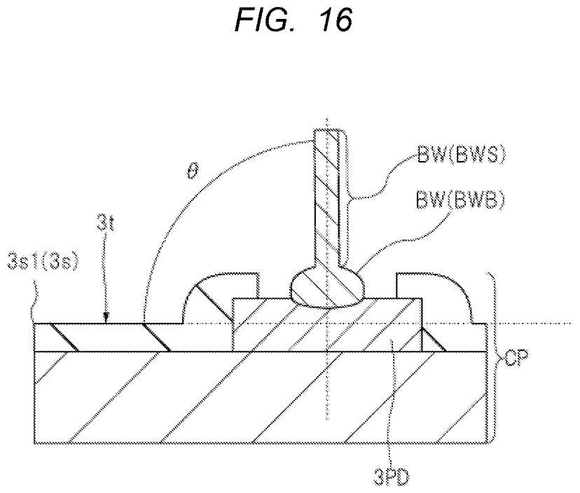

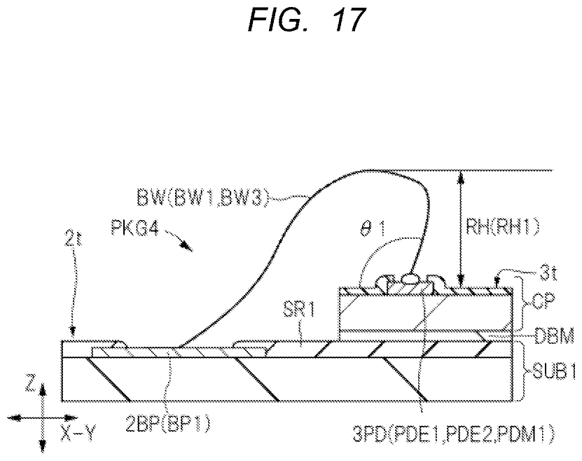

Next, a modified example of the loop shape of the wire BW explained by using FIGS. 7 to 11 will be described. FIG. 16 is an explanatory view for defining a neck angle of a wire. FIG. 17 is an enlarged cross-sectional view showing a modified example with respect to FIGS. 7 and 9. A semiconductor device PKG4 shown in FIG. 17 is the same as the semiconductor device PKG1 shown in FIGS. 1 to 11, the semiconductor device PKG2 shown in FIGS. 12 and 13, or the semiconductor device PKG3 shown in FIGS. 14 and 15, except for the loop shape of each of the wire BW1 and the wire BW3. Therefore, redundant description will be omitted, and the description will be made with reference to the drawings which have already been described as necessary. For example, since the loop shape of the wire BW2 shown in FIG. 5, FIG. 12, or FIG. 14 is similar to that of FIG. 8, FIG. 8 is used as an explanation of the semiconductor device PKG4.

First, the definition of the “neck angle” will be described. As shown in FIG. 16, each of the plurality of wires BW shown in FIG. 4, FIG. 12, or FIG. 14 includes a ball portion BWB bonded to one of the plurality of electrodes 3PD, and a standing portion BWS connected to the ball portion BWB and extending upward of the semiconductor chip CP. An angle formed by a portion, which is located between the ball portion BWB and the side 3s1, of the upper surface 3t of the semiconductor chip CP and the standing portion BWS is defined as a neck angle θ. The “neck angle θ” is a generic term for the neck angle of each of the plurality of wires BW, and includes the neck angle θ1 shown in FIG. 17 and the neck angle θ2 shown in FIG. 8.

The above-described side 3s1 is used for defining the neck-angle θ of the wire BW extending across the side 3s1 in plan view. For example, in FIG. 4, when the necking angle of the wire 3s2 extending across the side 3s2 BW is defined, the side 3s1 is replaced with the side 3s2. The same applies to the side 3s3 or the side 3s4 shown in FIG. 4.

The neck angle θ1 of the wire BW1 shown in FIG. 17 is greater than the neck angle θ2 of the wire BW2 shown in FIG. 8 and greater than 90 degrees. Similarly, the neck angle θ1 of the wire BW3 shown in FIG. 17 is greater than the neck angle θ2 of the wire BW2 shown in FIG. 8 and greater than 90 degrees.

When the neck angle θ1 is greater than 90 degrees, such as the wire BW1 and the wire BW3 shown in FIG. 17, a crack or peeling hardly occur at the joint portion between the wire BW and the electrode 3PD even if a stress concentration occurs, as compared with a wire BW2 in which the neck angle θ2 shown in FIG. 8 is 90 degrees or less.

Therefore, in addition to the measures described with reference to the drawings of FIGS. 5 to 15, by applying the structure (configuration) of the modified example shown in FIG. 17 to the wire BW1 and the wire BW3 to which the largest stress concentration is affected, it is possible to further improve the bonding reliability of the plurality of wires BW to the semiconductor chip CP.

In FIG. 17, the wire BW1 and the wire BW3 shown in FIG. 5, FIG. 6, FIG. 12, or FIG. 14 are illustrated with the neck angle θ1 greater than 90 degrees. As a modified example, the wire BW6 and the wire BW7 shown in FIG. 12 or 14 may be illustrated with the neck angle greater than 90 degrees.

While the embodiments and the exemplary modified example have been described above with reference to the drawings, various modified example can be applied to the above-described techniques in addition to the modified example described above. For example, in the above-described embodiments and modified example, among the plurality of electrodes 3PD arranged along the respective sides of the semiconductor chip CP, the loop height and the loop shape of the wire BW connected to the electrode 3PD arranged along the side 3s1 have been described. The above-described technique can be applied to each of the side 3s2, the side 3s3 and the side 3s3 shown in FIG. 4.

In the above-described embodiments and modified example, although one corner portion electrode is provided in each corner region 3CR, the number of corner portion electrodes is not limited to one, and may be two or more. Further, in this case, a part of the wires connected to the plurality of corner portion electrodes has the same loop height as the wire BW1, and another part has the same loop height as the wire BW6 shown in FIG. 15 in some cases.

Furthermore, some or all of the configurations of the above-described embodiments and modified example can be combined with other modified example and applied.

Although the invention made by the present inventor has been specifically described based on the embodiment, the present invention is not limited to the above embodiment, and it is needless to say that various modifications can be made without departing from the gist thereof.

What is claimed is:

1. A semiconductor device comprising:
a wiring substrate having: a first surface, and a plurality of terminals arranged on the first surface;
a semiconductor chip having: a second surface facing the first surface, a third surface opposite the second surface, and a plurality of electrodes arranged on the third surface, the semiconductor chip being mounted on the wiring substrate;
a plurality of wires electrically connecting the plurality of electrodes and the plurality of terminals, respectively, with each other; and
a sealing body sealing the semiconductor chip, the plurality of wires, and the first surface of the wiring substrate,
wherein the plurality of electrodes includes a plurality of first row electrodes arranged along a first side of the third surface, any ones of the plurality of wires being connected with the plurality of first row electrodes,
wherein the plurality of first row electrodes includes:
a first end portion electrode arranged at a one end portion of an arrangement of the plurality of first row electrodes;
a second end portion electrode arranged at an another end portion of the arrangement of the plurality of first row electrodes; and
a first non-end portion electrode arranged between the first end portion electrode and the second end portion electrode,
wherein the plurality of terminals includes:
a first terminal; and
a second terminal,
wherein the plurality of wires includes:
a first wire connected to each of the first end portion electrode and the first terminal; and
a second wire connected to each of the first non-end portion electrode and the second terminal, and
wherein a loop height of the first wire is greater than a loop height of the second wire.

2. The semiconductor device according to claim 1,
wherein the plurality of terminals further includes a third terminal,
wherein the plurality of wires further includes a third wire connected to each of the second end portion electrode and the third terminal, and
wherein a loop height of the third wire is greater than the loop height of the second wire.

3. The semiconductor device according to claim 2,
wherein, in plan view, the third surface has:
a second side crossing the first side; and
a third side crossing the first side and opposite the second side,
wherein when 20% of a length of the first side is a first length,
a distance between the first end portion electrode and the second side is less than the first length;
each of a distance between the first non-end portion electrode and the second side and a distance between the first non-end portion electrode and the third side is larger than the first length; and
a distance between the second end portion electrode and the third side is less than the first length.

4. The semiconductor device according to claim 2,
wherein the plurality of electrodes includes a plurality of second row electrodes arranged along the first side of the semiconductor chip and arranged far away from the first side than the plurality of first row electrodes, any ones of the plurality of wires being connected with the plurality of second row electrodes,
wherein the plurality of wires includes:
a plurality of first row wires connected to each of any ones of the plurality of first row electrodes and any ones of the plurality of terminals, respectively; and
a plurality of second row wires connected to each of any ones of the plurality of second row electrodes and any ones of the plurality of terminals, respectively, and
wherein a loop height of each of the plurality of second row wires is greater than a loop height of the second wire.

5. The semiconductor device according to claim 4, wherein the loop height of each of the plurality of second row wires is equal to each other.

6. The semiconductor device according to claim 5, wherein the loop height of each of the plurality of second row wires is equal to the loop height of the first wire.

7. The semiconductor device according to claim 4,
wherein the plurality of terminals includes:
a plurality of first row terminals arranged in a first direction; and
a plurality of second row terminals arranged in the first direction and arranged far away from the semiconductor chip than the plurality of first row terminals,
wherein the plurality of first row wires is connected to the plurality of first row terminals, respectively, and
wherein the plurality of second row wires is connected to the plurality of second row terminals, respectively.

8. The semiconductor device according to claim 4,
wherein the plurality of first row electrodes further includes a first corner portion electrode arranged next to the first end portion electrode,
wherein the plurality of wires further includes a fourth wire connected to each of the first corner portion electrode and a fourth terminal of the plurality of terminals, and
wherein a loop height of the fourth wire is greater than the loop height of the second wire.

9. The semiconductor device according to claim 8, wherein the loop height of the fourth wire is smaller than the loop height of each of the plurality of second row wires, and greater than the loop height of the second wire.

10. The semiconductor device according to claim 9, wherein the fourth wire crosses any ones of the plurality of second row electrodes.

11. The semiconductor device according to claim 1,
wherein each of the plurality of wires includes:
a ball portion connected to any one of the plurality of electrodes; and
a standing portion connected to the ball portion and extended upward of the semiconductor chip, and
wherein when an angle formed by a portion, which is located between the ball portion and the first side, of the third surface of the semiconductor chip and the standing portion is defined as a neck angle, a neck angle of the first wire is greater than a neck angle of the second wire, and greater than 90 degrees.
